(19) United States
(12) Patent Application Publication
(10) Pub. No.: US 2017/0030953 A1
(43) Pub. Date: Feb. 2, 2017

(54) SYSTEM FOR DYNAMIC MONITORING OF A MACHINE

(71) Applicant: Metrix Instrument Co., LP, Houston, TX (US)

(72) Inventors: Matthew Allen Nelson, Gardnerville, NM (US); Jonathan Daniel Fox, Carson City, NV (US); Jeremiah Robert Ferguson, Carson City, NV (US)

(21) Appl. No.: 15/223,093

(22) Filed: Jul. 29, 2016

Related U.S. Application Data
(60) Provisional application No. 62/199,551, filed on Jul. 31, 2015.

(51) Int. Cl. G01R 23/16

(52) U.S. Cl. CPC G01R 23/16

(57) ABSTRACT

A monitoring system having one or more sensors configured for providing dynamic information from one or more machinery assets, wherein in the system continuously samples monitoring data under predetermined states of the machine.

### CROSS-REFERENCE TO RELATED APPLICATIONS

This utility application claims the benefit under 35 U.S.C. §119(e) of Provisional Application Ser. No. 62/199,551, which was filed on Jul. 31, 2015, entitled System for Dynamic Monitoring of a Machine. The entire disclosure of this provisional application is incorporated by reference herein.

### FIELD OF THE INVENTION

This invention relates generally to data storage, and more particularly to the data collection and storage of dynamic data, for example, in condition based monitoring of machinery conditions.

### BACKGROUND OF THE INVENTION

In condition based monitoring, it is necessary to view dynamic waveform data in order to determine the cause of machine faults. This data is viewed in a variety of formats including spectrum, time-base, and X-Y two-dimensional plot known as the “orbit”. Historically, most continuous on-line systems collect the machine data in waveform “snapshots” consisting of periodically collected waveforms of a relatively short duration in comparison to the overall machine event. The periodic waveforms collected on intervals of time, speed, or other variable are limited to a data sample of sufficient length to present one pre-configured orbit or time-base plot of configured number of revolutions or a spectrum with a configured resolution. This approach works well for machines that experience transient events that occur over time periods ranging from minutes to hours, but provides very limited data for machines that experience very rapid transient events that occur over periods of 10 seconds or even less.

One known solution to overcome this problem is to use continuous sampling to record a machine event. Recording data continuously for long periods of time typically requires a very large data storage device. Machine startups often include ramping the machine up to an intermediate speed and allowing the machine to “soak” to let the machine components stabilize in temperature before continuing the speed ramp. This constant speed interval is often much longer than the transient speed interval and does not provide significant useful data. Recording and storing soak data results in large files that are difficult to store and transmit.

The solution to this problem is to collect data continuously over the duration of the transient event while suspending data collection during steady speed intervals and combining the data with the processing methods outlined in this disclosure.

Historically, previous solutions were not able to collect continuous data because they relied on using networks to move the data to a central location. These networks may have been internal to the product or external between the data collection instruments and a storage computer. When collecting many channels of data, the dynamic data can become very large: Waveforms consisting of 32 bit samples collected at a rate of 51,200 samples/second for 48 channels is 78.6 Mbps. Since it is beneficial to sample the data at two different rates to optimize the data for viewing in the time-base format vs. the spectral form, with framing and other network overhead the required data rate can easily exceed 200 Mbps. A network of this speed requires expensive fast processing hardware and consumes significant power.

Previous systems have used the concept of overlapping data for spectrum generation. However, these systems required the user to configure the percentage of overlap which may or may not result in a high resolution plot depending on the machine transient conditions.

### SUMMARY OF THE INVENTION

A first aspect of the invention is a system for dynamic monitoring of a machine, which includes one or more sensors configured to measure parameters on the machine, a microcomputer configured to collect dynamic waveform data from said sensors continuously when said microcomputer detects the machine is in a transient condition, and local memory for storing said dynamic waveform data continuously during said transient condition. The microcomputer is configured to enter or exit continuous data collection automatically based on an index calculated from a combination of one or more of the measured parameters.

In a further aspect of the first aspect of the invention, at least one of the measured parameters is selected from one of the group consisting of: speed, AC amplitude, DC bias, and phase.

In a further aspect of the first aspect of the invention the microcomputer is further configured to display dynamic waveform data based on the stored dynamic waveform data in a plotted form.

In a further aspect of the first aspect of the invention, the microcomputer is further configured to apply a fast Fourier transform to overlapping segments of the dynamic waveform data to produce a series of spectral plots of said data. In a further aspect of this, the microcomputer is further configured to base an amount of overlapping on plot resolution. In a further aspect of this, the microcomputer is further configured to automatically increase the amount of overlapping as a plot time range is zoomed in.

A second aspect of the invention is a method for continuous data sampling of a machine monitoring sensor. The method includes the steps of monitoring sensor data continuously during operation of the machine, and starting and stopping continuous data sampling automatically based on changes in at least one machine parameter selected from the group consisting of speed, vibration amplitude, and vibration phase.

In a further aspect of this second aspect of the invention, the starting and stopping is based on changes in speed and wherein a speed change threshold is manually configurable.

### BRIEF DESCRIPTION OF THE DRAWINGS

FIG. 1 is a block diagram of an exemplary system according to the invention;

FIG. 2 is timing diagram of an exemplary overlapping technique;

FIG. 3 is an exemplary waterfall plot of a 5 second startup in continuous sampling mode;

FIG. 4 is an exemplary waterfall plot of a 7 second startup in non-continuous sampling mode; and

FIG. 5 is an exemplary set of plots showing a sampling suspension during a soak interval.

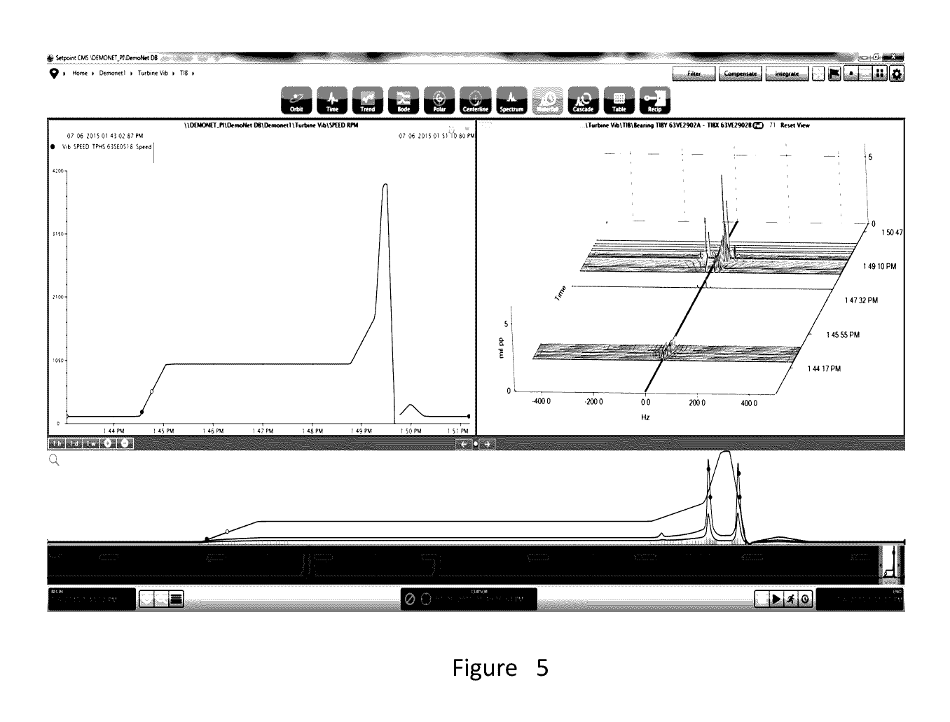

### DETAILED DESCRIPTION OF THE INVENTION

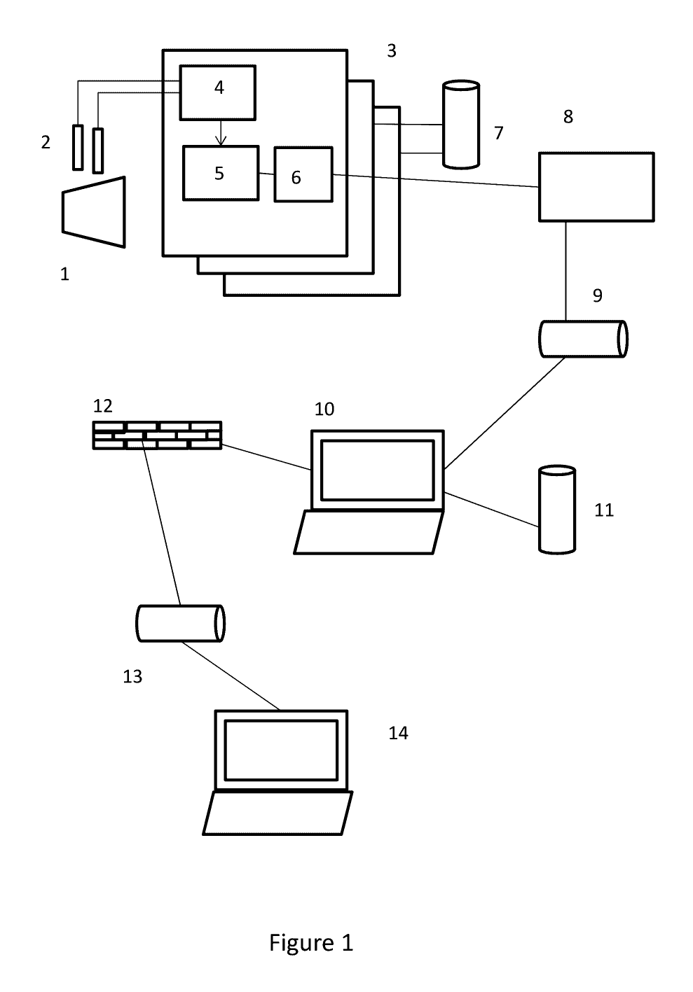

Referring to FIG. 1: there is disclosed a monitoring system having one or more sensors 2 providing dynamic information from one or more machinery assets 1. Sensor data passes to one or more data collection modules 3. The data collection module 3 includes hardware that conditions the sensor signal and digitizes the signal at a sample rate sufficient to display the signal dynamic content 4. The data collection module 3 includes a fast memory storage device located in proximity with the sampling hardware. This memory device is capable of storing continuous data over the transient event duration. The data collection module 3 includes the ability to move the data over a network 7 from the fast memory storage to a device that aggregates the data across multiple modules 8.

An aggregation device 8 moves the data via a network 9 to a server device 10 with external storage database 11 that is capable of storing the data as a continuous waveform sample in time. This database 11 is a non-proprietary historian database such as Osisoft's PI® System. Means for secure networking the server 9 through a firewall 12 to a network 13 where users can view the data on display devices 14.

Display means (not shown) are provided for extracting the data from the database by time, allowing the data to be overlapped. The overlapping is done automatically by the system to provide the user configured number of spectrums to be plotted.

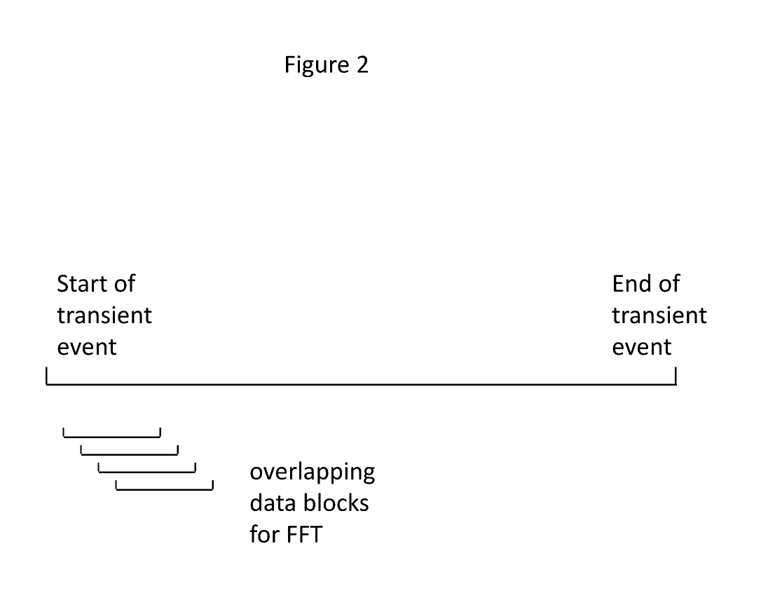

The Fast Fourier Transform (FFT) used to present a spectral analysis of the sampled data requires a fixed number of samples (for example, a block of 2048 samples are required for an 800 line spectrum). The block of samples used in the FFT processing is progressively stepped through the continuous stream of data processing FFTs, so that the blocks of samples used for the FFT can overlap each other, re-using some of the data to create the new FFT. This process is visually represented in FIG. 2.

### Entering/Exiting Continuous Sampling Mode

As stated previously, it is not practical or desirable to continuously collect and store data for all channels. Therefore it is necessary to enter and exit the continuous sampling state. By gating a continuous sampling mode by transient event frames, high density data is only collected when the machine is in an interesting or non-steady state condition. This reduces the requirement for high bandwidth networks and large high throughput memory storage devices. Data is considered interesting when the signal is determined to be changing parameters such as filtered AC amplitude, DC bias, phase, frequency content, or other measured parameter. Gating the continuous data recording by how interesting the data is suspends data collection during soak intervals where the machine speed or other measurements are not changing. The system uses a configuration value input by the user to tell the system how much speed or other parameter variation is allowable during the soak region to not trigger continuous sampling. When the machine speed stabilizes to less than the set threshold, continuous sampling is suspended until the system detects that the speed is again changing.

A transient event frame may be triggered by a user directly via a software command or a hardware contact, by entering a configured transient speed region, or by analysis (or interestingness) of available machine parameters. A transient frame may be exited by a software command or release of a hardware contact, exiting a configured transient speed region, machine returning to a steady state condition, or by a fixed timer expiring. These triggers may be used in isolation or in any desired combination to produce the desired results.

### Zooming in on Continuous Sampling Mode Data

Data sets can be viewed in various ways. For example, one can zoom in on a timeline representation to produce an increasingly detailed waterfall plot. For example, in a 4 second start-up, 100 waveforms can be displayed to show what happened. No matter what time range is selected consistent density of spectral data will be shown.

The overlap percentage will be set automatically based on the number of collected waveforms present in the selected time range. The goal is to provide a consistent density of spectral data that does not obscure features in the data no matter how small or large the zoom range.

A consistent density of waveform can be maintained by use of an algorithm such as this: when more waveforms than the Overlap Threshold, turn off overlap, otherwise overlap is (Actual Waveform Count/Overlap Threshold)*100=Percent Overlap. Overlap Threshold=100. The physical waveforms collected will cause the overlap percent to go up, and the more waveforms collected overlap decreases until the threshold is reached, at which point overlapping is turned off entirely.

### Invention Benefits

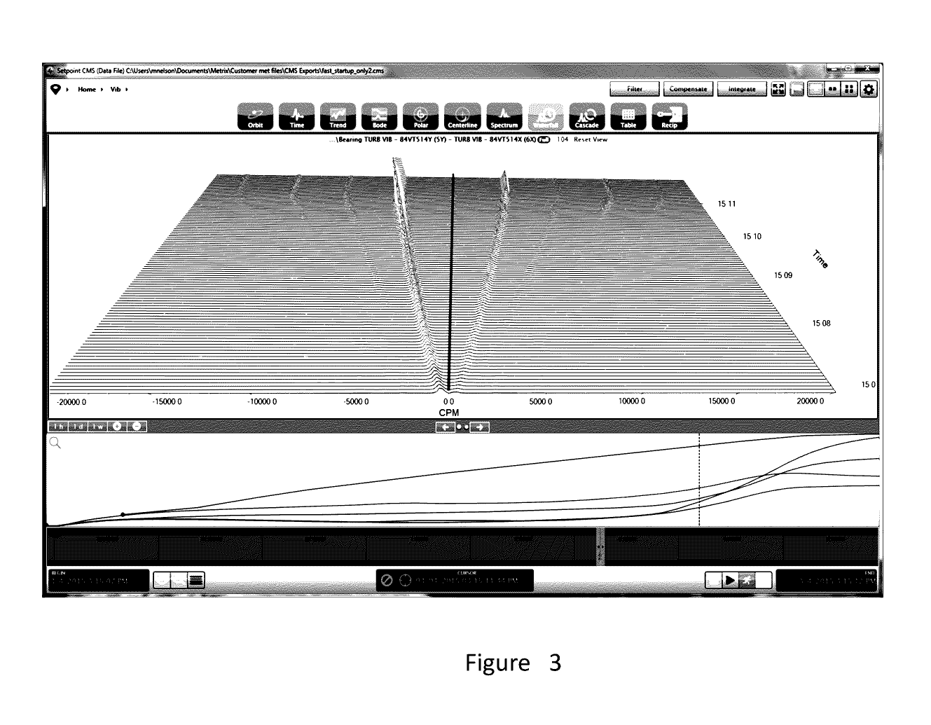

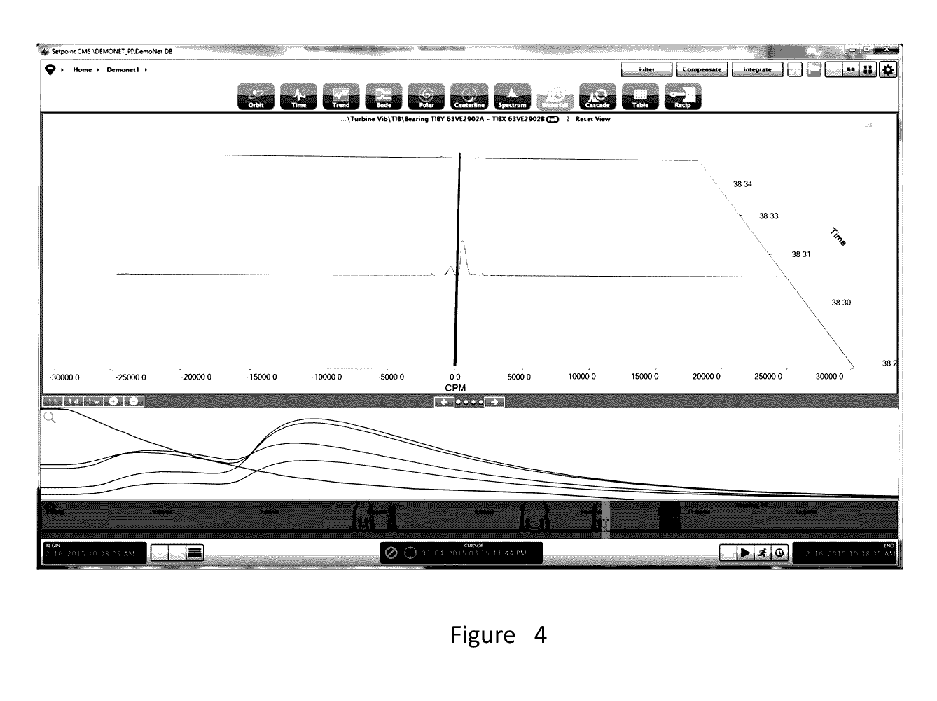

The benefits of this invention are shown in FIG. 3: Waterfall Plot of a 5 Second Startup in Continuous Sampling Mode. When this is compared with data taken in snapshots (FIG. 4) the difference is readily apparent.

What is claimed is:

1. A system for dynamic monitoring of a machine comprising:
one or more sensors configured to measure parameters on the machine,
a microcomputer configured to collect dynamic waveform data from said sensors continuously when said microcomputer detects the machine is in a transient condition, and
local memory for storing said dynamic waveform data continuously during said transient condition,
wherein said microcomputer is configured to enter or exit continuous data collection automatically based on an index calculated from a combination of one or more of said measured parameters.

2. There system of claim 1, wherein at least one of said measured parameters is selected from one of the group consisting of: speed, AC amplitude, DC bias, and phase.

3. The system of claim 1, wherein said microcomputer is further configured to display dynamic waveform data based on said stored dynamic waveform data in a plotted form.

4. The system of claim 3, wherein said microcomputer is further configured to apply a fast Fourier transform to overlapping segments of said dynamic waveform data to produce a series of spectral plots of said data.

5. The system of claim 4, wherein said microcomputer is further configured to base an amount of overlapping on plot resolution.

6. The system of claim 5, wherein said microcomputer is further configured to automatically increase said amount of overlapping as a plot time range is zoomed in.

7. A method for continuous data sampling of a machine monitoring sensor comprising:
monitoring sensor data continuously during operation of the machine, and
starting and stopping continuous data sampling automatically based on changes in at least one machine parameter selected from the group consisting of speed, vibration amplitude, and vibration phase.

8. The method of claim 7, wherein said starting and stopping is based on changes in speed and wherein a speed change threshold is manually configurable.
